(19) United States
(12) Patent Application Publication
(10) Pub. No.: US 2012/0024573 A1
(43) Pub. Date: Feb. 2, 2012

(54) Printed circuit board and manufacturing method thereof

(75) Inventors: Jae Hun Kim, Seoul (KR); Ji Han Kwon, Suwon (KR); Ha Yoon Song, Hwaseong (KR); Young Seuck Yoo, Seoul (KR); Hee Jin Park, Suwon (KR); Jun Young Kim, Suwon (KR); Ju Hwan Yang, Suwon (KR); Sung Nam Cho, Buyeo-gun (KR)

(73) Assignee: SAMSUNG ELECTRO-MECHANICS CO., LTD., Suwon (KR)

(21) Appl. No.: 13/067,136

(22) Filed: May 11, 2011

(30) Foreign Application Priority Data
Jul. 29, 2010 (KR) 10-2010-0073639

(51) Int. Cl. H05K 1/00; H05K 3/12

(52) U.S. Cl. 174/250; 427/98.5

(57) ABSTRACT

There are provided a printed circuit board and a manufacturing method thereof. The manufacturing method of a printed circuit board includes: preparing a substrate having active regions and non-active regions, the non-active regions being formed on edges thereof; printing resists on dummy portions corresponding to the non-active regions of the substrate by using an inkjet printing method; curing the resists; and performing plating on the active regions of the substrate. The resists are masked on the dummy portions corresponding to the non-active regions of the substrate to prevent plating from being performed on the dummy portions, thereby reducing manufacturing costs.

### CROSS-REFERENCE TO RELATED APPLICATIONS

This application claims the priority of Korean Patent Application No. 10-2010-0073639 filed on Jul. 29, 2010, in the Korean Intellectual Property Office, the disclosure of which is incorporated herein by reference.

### BACKGROUND OF THE INVENTION

1. Field of the Invention

The present invention relates to a printed circuit board and a manufacturing method thereof, and more particularly, to a printed circuit board and a manufacturing method thereof capable of preventing plating from being performed on dummy portions thereof during a plating process.

2. Description of the Related Art

According to the related art, two surfaces of a substrate are coated with a photo solder resists (PSR) by using a screen printing method and a roll printing method. The PRS may be patterned on the substrate through exposure and development so that the PRS is formed only on desired portions of the substrate.

However, since a clamp and an absorption pad for transporting the substrate after a screen printing process is performed are attached to edge portions of the substrate when the PSR is patterned thereon, dummy portions in which the PSR is not formed are formed at the edge portions of the substrate.

Since the PSR is not formed on the dummy portions, plating is performed up to the dummy portions of the edge portions of the substrate during a plating process, thereby causing an increase in manufacturing costs.

### SUMMARY OF THE INVENTION

An aspect of the present invention provides a manufacturing method of a printed circuit board capable of preventing plating from being unnecessarily performed on dummy portions during a plating process by masking resists on the dummy portions corresponding to non-active regions of a substrate using an inkjet printing method

According to an aspect of the present invention, there is provided a manufacturing method of a printed circuit board, including: preparing a substrate having active regions and non-active regions, the non-active regions being formed on edges thereof; printing resists on dummy portions corresponding to the non-active regions of the substrate by using an inkjet printingmethod; curing the resists; and performing plating on the active regions of the substrate.

The manufacturing method may further include selecting the dummy portions formed on the substrate by imaging the substrate before printing the resists.

The resists may be photo-curable resists or heat-curable resists.

The plating may be an Au plating.

The manufacturing method may further include, prior to the performing of plating on the active regions of the substrate, printing theresists on dummy portions of another surface of the substrate on which the resists are not formed; and curing the resists.

The printing of the resists may include simultaneously forming the resists on the dummy portions formed on both surfaces of the substrate.

The printing of the resists may include pre-curing the resists while printing the resists.

According to another aspect of the present invention, there is provided a printed circuit board, including: a substrate having active regions and non-active regions, the non-active regions being formed on edges thereof; and resists printed on dummy portions corresponding to the non-active regions of the substrate by using an inkjet printing method.

The resists may be photo-curable resists or heat-curable resists.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a flow chart schematically showing a resist forming process according to an exemplary embodiment of the present invention;

FIGS. 2A to 2C are process flow charts schematically showing a resist forming process according to an exemplary embodiment of the present invention;

FIG. 3 is a plan view showing a substrate having resists formed thereon according to an exemplary embodiment of the present invention; and

FIGS. 4A and 4B are cross-sectional views showing a resist printing process on the substrate according to an exemplary embodiment of the present invention.

### DETAILED DESCRIPTION OF THE PREFERRED EMBODIMENT

Exemplary embodiments of the present invention will be described with reference to the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the shape, size, and the like, of components are exaggerated for clarity.

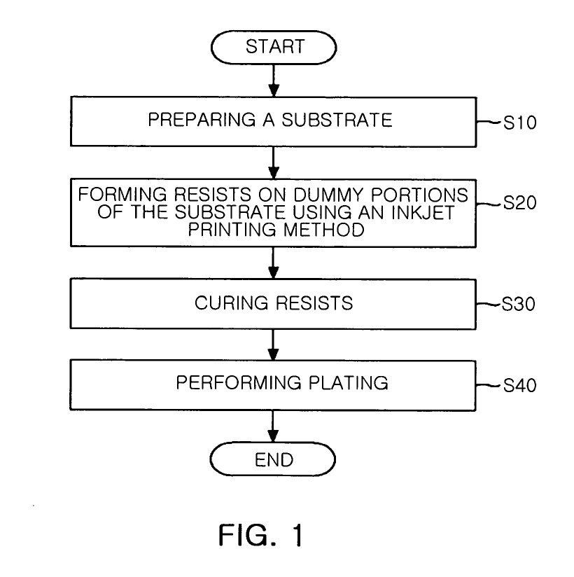

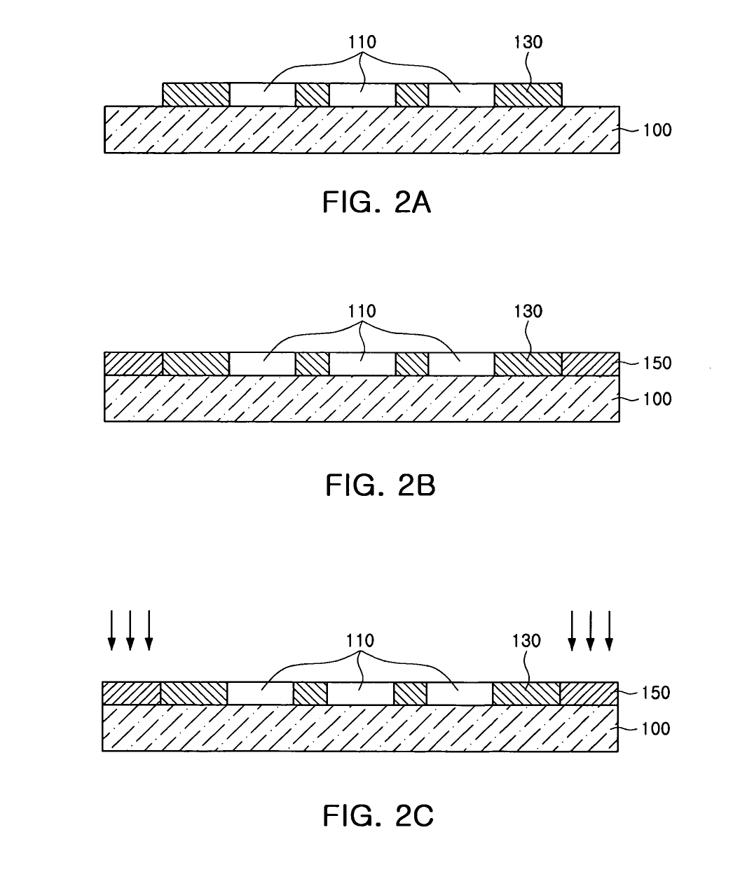

FIG. 1 is a flow chart schematically showing a resist forming process according to an exemplary embodiment of the present invention, and FIGS. 2A to 2C are process flow charts schematically showing a resist forming process according to an exemplary embodiment of the present invention.

Hereinafter, a manufacturing method of a printed circuit board according to an exemplary embodiment of the present invention shown in FIG. 1 will be described according to manufacturing process shown in FIGS. 2A to 2C.

According to an exemplary embodiment of the present invention, in operation (S10), a substrate having pads formed on one surface thereof and having first resists formed on remaining portions thereof, excluding the pads, so that plating is performed only on the pads, is prepared. The first resists are formed on portions of the substrate, excluding the pads, in order that plating may be performed on the pads.

In operation (S20), second resists are formed on dummy portions of the substrate using an inkjet printing method. A process of determining the dummy portions is required in order to form the second resists. In order to determine the dummy portions, an imaging process may be performed. The dummy portions of the substrate may be determined in consideration of the contraction and the deformation of the substrate through the imaging process.

On the substrate, the dummy portions, corresponding to non-active portions on which circuits are not to be formed refer to portions required for manufacturing the substrate. For example, the dummy portions may be portions to which a clamp for transporting the substrate and an absorption pad are attached.

After the second resists are formed on the substrate using the inkjet printing method, the second resists are cured in operation (S30). The second resists may be photo-curable resists or thermo-curable resists. Accordingly, the second resists may be cured by light or heat, according to the characteristics thereof.

In operation (S40), a plating process is performed on the substrate having the first and second resists formed thereon. In particular, the plating process may be a gold (Au) plating process. In the case that gold is unnecessarily plated on the dummy portions, high manufacturing costs may be incurred.

According to an exemplary embodiment of the present invention, the second resists are formed on the dummy portions of the substrate to prevent gold from being unnecessarily plated thereon, such that manufacturing costs may be reduced.

Hereinafter, a manufacturing process of a printed circuit board according to an exemplary embodiment of the present invention will be described with reference to FIGS. 2A to 2C.

Referring to FIG. 2A, according to an exemplary embodiment of the present invention, a substrate, having pads 110 formed on a surface thereof and having first resists 130 formed on portions of a substrate, excluding portions on which the pads 110 are formed, so that plating may be performed on surfaces of the pads 110 is prepared.

According to an exemplary embodiment of the present invention, the first resists 130 may be formed as, for example, photo solder resists (PSRs); however the first resists 130 are not limited thereto. The first resists 130 serve to prevent portions of the substrate from being plated, with the exception of the pads 110, in active portions in which circuits of the substrate are formed.

The first resists 130 which may be photo solder resists are formed on the substrate 100, and may be selectively cured in consideration of a pattern to be cured. For example, the portions of the substrate, other than the pads 110, are selectively cured using a method such as an exposure method, or the like.

The photo solder resists formed on the pads 110 of the substrate 100 are selectively removed, such that the pads 110 are exposed

The substrate 100, on which only the pads 110 are exposed, and having the first resists 130 formed on the remaining portions thereof is prepared, such that when a plating process is performed on the substrate 100, only the pads 110 of the substrate 100 may be plated.

Referring to FIG. 2B, second resists 150 are formed on the outermost dummy portions of the substrate 100.

The first resists 130 may not be formed on the dummy portions corresponding to non-active regions of the substrate 100.

Accordingly, the second resists 150 are formed such that the dummy portions of the substrate 100 are not plated. The second resists 150 may be formed by using the inkjet printing method.

The selection of dummy portions is required in order to apply the second resists 150 to the substrate 100.

Dummy portions indicate non-active regions of the substrate in which circuits are not to be formed. Dummy portions may also be regions required for attaching a clamp or an absorption pad, in a substrate manufacturing process.

Dummy portions indicate the non-active regions of the substrate formed at the edge portions of the substrate.

Meanwhile, according to an exemplary embodiment of the present invention, among the edge portions of the substrate, the second resists 150 may not be formed on a test terminal for testing the substrate, a plating deviation prevention pattern for preventing plating deviation during the plating of the substrate, a transport hole for transporting the substrate, and a printing target on which printing, such as screen printing or the like, will be performed.

Since the test terminal, the plating deviation prevention pattern, the transport hole, and the printing target need to be active portions in the manufacturing and testing process of the substrate, the second resists maybe not formed on these portions.

According to an exemplary embodiment of the present invention, an imaging process is used in order to select the regions in which the second resists 150 are to be formed on the substrate 100.

First, the substrate 100, having the first resists 130 formed on portions thereof, other than the pads 110, is prepared. The first resists may be PSRs. The substrate 100 is imaged by an image apparatus such as a camera, or the like.

For example, an image of the substrate is converted into a printable bit map file format. Then, a substrate device is arranged to measure a change in the size of the substrate generated in passing through a previous process, thereby performing a conversion that increases or decreases the size of the image of the bit map file according to the substrate.

Through this conversion, second resist application regions may be selected by considering deformation due to the manufacturing process of the substrate. Thereafter, the second resists 150 may be applied to the selected second resist application regions.

FIG. 2C is a view showing a curing process of the second resists 150 according to an exemplary embodiment of the present invention.

The second resists 150, formed using the above-mentioned method are cured according to the characteristics of a material of which they are composed.

According to an exemplary embodiment of the present invention, the second resists 150 may be thermo-curable resists or photo-curable resists; however the present invention is not limited thereto. When the second resists 150 are the thermo-curable resists, the second resist 150 may be cured by applying heat thereto. Alternatively, when the second resists 150 are the photo-curable resist, the second resists 150 may be cured by being exposed to light.

According to an exemplary embodiment of the present invention, since the second resists 150 are applied by using the inkjet printing method, a removal process thereof is not required. The formed resists may be only cured to be used in the next process.

Since the second resists 150 are applied using the inkjet printing method, second resist application regions in which the second resists 150 are to be formed may be accurately selected and a removal process thereof is not required, and thus, the manufacturing efficiency of the printed circuit board may be improved.

Then, a plating process is performed on the substrate on which the first and second resists 130 and 150 are formed. For example, a gold plating process may be performed on the substrate.

When the gold plating process is performed, gold is not plated on the regions on which the resists are formed, thereby preventing the gold from being plated on portions not requiring gold plating, such that manufacturing efficiency may be improved and manufacturing costs may be lowered.

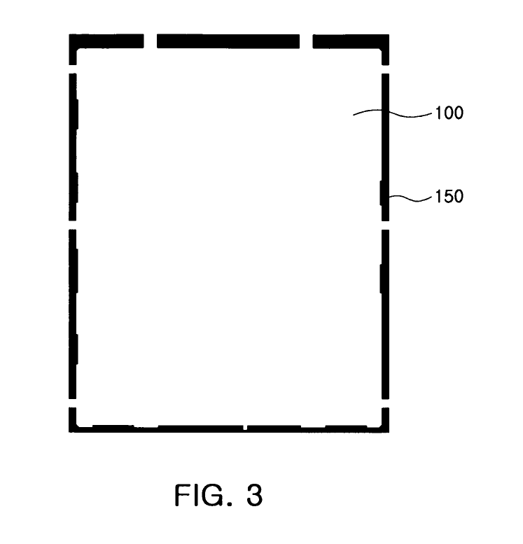

FIG. 3 is a plan view showing a substrate having resists formed thereon according to an exemplary embodiment of the present invention.

In FIG. 3, the second resists 150 are formed on the substrate 100 and particularly, the second resists 150 are not formed in predetermined active portions among the edge dummy portions of the substrate.

Since the imaging process is performed prior to printing the second resists 150, the substrate may be manufactured by considering the deformation of the substrate during the manufacturing of the substrate. Therefore, the reliability of the substrate may be improved.

In addition, since the resists are formed using the inkjet printing method, resists may be accurately formed in desired portions as well as the resists may be formed excluding, predetermined active portions in the manufacturing process of the substrate, for example, the test terminal, the printing target, the plating deviation prevention pattern, the substrate transport hole, and the like.

Further, since the resists are partially formed, a process of removing the resists formed at the unnecessary portion after the resists are cured is not required, thereby significantly simplifying the process.

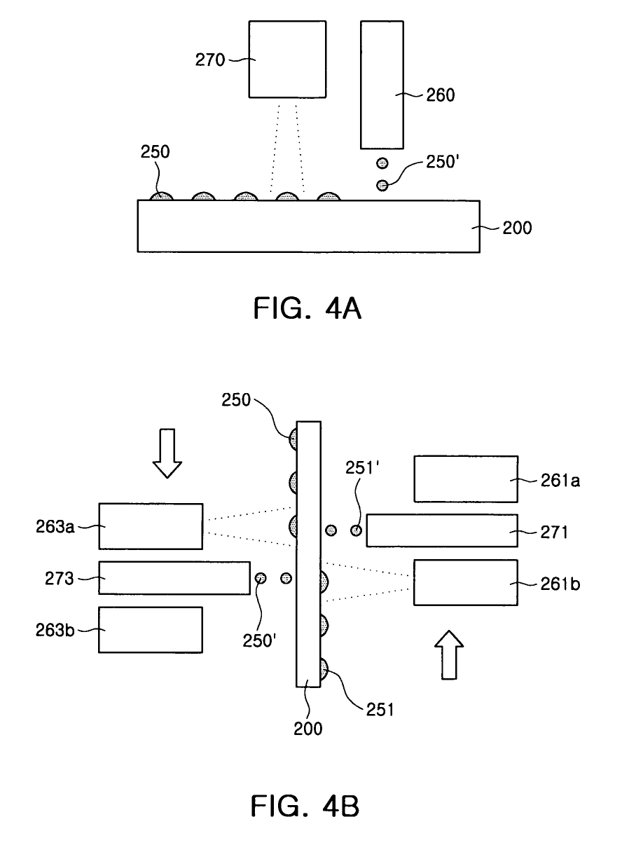

FIGS. 4A and 4B are cross-sectional views showing a process of printing the resists on the substrate according to an exemplary embodiment of the present invention.

Referring to FIG. 4A, resists 250′ are discharged from an inkjet head 260 to a substrate 200 to form second resists 250 on the substrate 200.

According to an exemplary embodiment of the present invention, a pre-curing unit 270 may be provided next to the inkjet head 260. After the resists 250′ are discharged from the inkjet head 260, the pre-curing unit 270 may pre-cure the second resists 250 by passing on the resists 250′.

The second resists 250 are formed while being cured through the pre-curing process, such that the resist may be stably formed.

In the case of FIG. 4A, the second resists are formed on one surface of the substrate, the substrate is cured, the second resists are formed on another surface of the substrate, and then the substrate is cured.

According to another exemplary embodiment of the present invention, a method in which the second resists are simultaneously formed on both surfaces of the substrate and both surfaces are simultaneously cured to simplify a manufacturing process of the substrate is provided.

FIG. 4B shows a process in which the second resists 250 and 251 are simultaneously formed on both surfaces of the substrate 200.

The second resists 250′ and 251′ are simultaneously discharged through inkjet heads 271 and 273 horizontally moved with reference to the substrate 200, and pre-curing units 261a, 261b, 263a, and 263b passing through regions through which the inkjet heads have passed may pre-cure the discharged resists.

According to an exemplary embodiment of the present invention, the pre-curing units 261b and 263a are formed on both sides of the inkjet heads 271 and 273 to pre-cure the resists formed at the regions through which the inkjet heads have passed along a direction thereof.

Similar to this, the second resists 250 are simultaneously formed on both surfaces of the substrate 200, such that the process of manufacturing the substrate may be simplified and the manufacturing time thereof may be shortened.

As set forth above, according to the exemplary embodiments of the present invention, the resists are masked on the dummy portions corresponding to the non-active regions of the substrate to thereby prevent plating from being unnecessarily performed on the dummy portions during the plating process.

While the present invention has been shown and described in connection with the exemplary embodiments, it will be apparent to those skilled in the art that modifications and variations can be made without departing from the spirit and scope of the invention as defined by the appended claims.

What is claimed is:

1. A manufacturing method of a printed circuit board, comprising:
preparing a substrate having active regions and non-active regions, the non-active regions being formed on edges thereof;
printing resists on dummy portions corresponding to the non-active regions of the substrate by using an inkjet printingmethod;
curing the resists; and
performing plating on the active regions of the substrate.

2. The manufacturing method of claim 1, further comprising selecting the dummy portions formed on the substrate by imaging the substrate before printing the resists.

3. The manufacturing method of claim 1, wherein the resists are a photo-curable resists or a heat-curable resists.

4. The manufacturing method of claim 1, wherein the plating is an Au plating.

5. The manufacturing method of claim 1 further comprising:
prior to the performing of plating on the active regions of the substrate,
printing theresists on dummy portions of another surface of the substrate on which the resists are not formed; and
curing the resists.

6. The manufacturing method of claim 1, wherein the printing of the resists includes simultaneously forming the resists on the dummy portions formed on both surfaces of the substrate.

7. The manufacturing method of claim 1, wherein the printing of the resists includes pre-curing the resists while printing the resists.

8. A printed circuit board, comprising:
a substrate having active regions and non-active regions, the non-active regions being formed on edges thereof; and
resists printed on dummy portions corresponding to the non-active regions of the substrate by using an inkjet printing method.

9. The printed circuit board of claim 8, wherein the resists are photo-curable resists or heat-curable resists.
